(19) United States
(12) Patent Application Publication
(10) Pub. No.: US 2025/0220776 A1
(43) Pub. Date: Jul. 3, 2025

(54) Ceramic Susceptor

(71) Applicant: MiCo Ceramics Ltd., Anseong-si (KR)

(72) Inventor: Je Ho CHAE, Anseong-si (KR)

(21) Appl. No.: 19/002,839

(22) Filed: Dec. 27, 2024

(30) Foreign Application Priority Data
Dec. 28, 2023 (KR) 10-2023-0194823

(51) Int. Cl. H05B 3/14; H05B 1/02

(52) U.S. Cl. CPC H05B 3/141; H05B 1/0233; H05B 2203/005; H05B 2203/016

(57) ABSTRACT

Disclosed is a ceramic susceptor. The susceptor of the present disclosure may include an insulating plate in which a heating element is disposed, and a shaft joined to a bottom portion of the insulating plate. The heating element may include a first heating element pattern including a first resistance section and a first connecting section connected between a first pair of terminals. When the first resistance section is projected onto a plane of the insulating plate, the first resistance section may include a first central resistance section disposed within a smaller diameter region than a joint portion between the insulating plate and the shaft.

### CROSS-REFERENCE TO RELATED APPLICATION(S)

This application is based on and claims priority under 35 U.S.C. 119 to Korean Patent Application No. 10-2023-0194823, filed on Dec. 28, 2023, in the Korean Intellectual Property Office, the disclosure of which is herein incorporated by reference in its entirety.

### BACKGROUND OF THE INVENTION

### 1. Field of the invention

The present disclosure relates to a ceramic susceptor, and more particularly, to a ceramic susceptor intended to improve temperature uniformity and extend the lifespan of a heater pattern.

### 2. Description of the Prior Art

In general, a semiconductor device or a display device is manufactured by sequentially laminating multiple thin film layers including a dielectric layer and a metal layer on a glass substrate, a flexible substrate, or a semiconductor wafer substrate and then patterning the thin film layers. These thin film layers are sequentially deposited on the substrate through a chemical vapor deposition (CVD) process or a physical vapor deposition (PVD) process. The CVD process includes a low-pressure CVD (LPCVD) process, a plasma-enhanced CVD (PECVD) process, a metal-organic CVD (MOCVD) process, and the like. Ceramic susceptors are disposed in these CVD and PVD apparatuses to support glass substrates, flexible substrates, semiconductor wafer substrates, and the like, to generate a predetermined level of heat, or to generate plasma by radio-frequency (RF) electrodes. The ceramic susceptors are widely used in accordance with requirements of precise temperature control and heat treatment in plasma deposition processes or the like for precise processes such as miniaturization of wiring lines of semiconductor devices, and are also used for plasma formation or substrate heating in etching processes of thin film layers formed on semiconductor wafer substrates or photoresist firing processes.

A general ceramic susceptor includes a heating element for a heater function disposed between ceramic materials. In the ceramic susceptor structure, when the heating element is fed with power and generates heat to heat a semiconductor wafer substrate or the like, temperature uniformity in the substrate is important to improve yield through a stable semiconductor process.

FIG. 1 is a view illustrating a heating element pattern of a conventional ceramic susceptor.

Referring to FIG. 1, a conventional ceramic susceptor is generally provided with a heating element pattern 10 extending in an arc from a terminal pair 10a and 10b in the central portion on the same plane. The conventional heating element pattern 10 includes a hairpin section 20, which is a section that is sharply bent for folding in a narrow region in the central portion. That is, the hairpin section 20 near the terminal pair 10a and 10b has a sharp curve shape in which the radius of curvature is smaller than that of the adjacent folded section.

However, since this hairpin section 20 is a region with high pattern density per unit area and, thus high heat generation density, cracks may easily occur in that region due to long-term use. This is caused by thermal stress caused by differences in thermal expansion rates of the heating element embedded in the ceramic material. In the case of a ceramic susceptor used in a semiconductor process, especially in a deposition process, repeated exposure to heat cycle environments leads to the gradual formation of cracks on the surface of the ceramic susceptor, progressively degrading the functionality of the ceramic susceptor and eventually making the ceramic susceptor unusable.

### SUMMARY OF THE INVENTION

Accordingly, the present disclosure has been made to solve the above-described problems. The present disclosure provides a ceramic susceptor for improving temperature uniformity over the entire region of the top surface of the susceptor and improving the lifespan of a heater pattern by forming a heating element pattern without a hairpin section in the central portion of a susceptor plate having a high heating element embedding density.

In summary, a susceptor according to an aspect of the present disclosure may include an insulating plate in which a heating element is disposed, and a shaft joined to a bottom portion of the insulating plate. The heating element may include a first heating element pattern including a first resistance section and a first connecting section connected between a first pair of terminals. When the first resistance section is projected onto a plane of the insulating plate, the first resistance section may include a first central resistance section disposed within a smaller diameter region than a joint portion between the insulating plate and the shaft.

The first resistance section may include multiple arc sections extending in a circumferential direction and multiple folded sections connecting the arc sections, and the curve of the first central resistance section may be formed to intersect an extension line of an imaginary straight line passing through a space between adjacent folded sections which are spaced apart from each other.

The first resistance section may include multiple arc sections extending in a circumferential direction and multiple folded sections connecting the arc sections, and the curve of the first central resistance section may be formed to intersect an extension line of an imaginary line extending from the folded section closest to the first central resistance section.

The curve of the first central resistance section may be formed such that the curvature radius of a portion close to one of the first pair of terminals is larger than curvature radii of folded sections of the first resistance section.

The curvature radius of the portion close to one of the first pair of terminals may be at least twice as large as the maximum curvature radius of the folded sections of the first resistance section.

The curve of the first central resistance section may be formed such that the curvature radius of a portion close to one of the first pair of terminals is larger than a curvature radius of a closest folded section among the folded sections of the first resistance section.

The curve of the first central resistance section may be formed such that the curvature radius of a portion close to one of the first pair of terminals is larger than the curvature radius of a closest folded section among the folded sections of the first resistance section, and the curve of the second central resistance section may be formed such that the curvature radius of a portion close to one of the second pair of terminals is larger than the curvature radius of a closest folded section among the folded sections of the second resistance section.

The first pair of terminals may be disposed within the smaller diameter region than the joint portion between the insulating plate and the shaft.

The heating element may include a second heating element pattern including a second resistance section and a second connecting section connected between a second pair of terminals, and when the first and second resistance sections are projected onto the plane of the insulating plate, the second resistance section may include a second central resistance section disposed within the smaller diameter region than the joint portion between the insulating plate and the shaft.

The second resistance section may include multiple arc sections extending in a circumferential direction and multiple folded sections connecting the arc sections, and at least one of the curves of the first central resistance section and the second central resistance section is formed to intersect an extension line of an imaginary straight line passing through a space between adjacent folded sections which are spaced apart from each other.

The adjacent folded sections may include folded sections which are adjacent to a folded section of the first resistance section and a folded section of the second resistance section.

The second resistance section may include multiple arc sections extending in a circumferential direction and multiple folded sections connecting the arc sections, and at least one of the curves of the first central resistance section and the second central resistance section may be formed to intersect an extension line of an imaginary line extending from a folded section connected to the first central resistance section, which are closest to the first central resistance section or the second central resistance section.

The second resistance section may include multiple arc sections extending in a circumferential direction and multiple folded sections connecting the arc sections, and at least one of the curves of the first central resistance section and the second central resistance section may be formed to intersect an extension line of an imaginary line extending from a folded section connected to the second central resistance section, which are closest to the first central resistance section or the second central resistance section. The second resistance section may include multiple arc sections extending in a circumferential direction and multiple folded sections connecting the arc sections, and at least one of the curves of the first central resistance section and the second central resistance section may be formed to intersect respective extension lines of imaginary lines extending from folded sections connected to the first central resistance section and the second central resistance section, which are closest to the first central resistance section and the second central resistance section, respectively.

The curves of the first central resistance section and the second central resistance section may be formed such that the curvature radius of a portion close to one of each pair of terminals is larger than the curvature radius at each of the folded sections of the first resistance section and the second resistance section.

The curvature radius of a portion close to one of each pair of terminals may be at least twice as large as a maximum curvature radius of the folded sections of the first resistance section and the second resistance section.

The second pair of terminals may be disposed within the smaller diameter region than the joint portion between the insulating plate and the shaft.

With the ceramic susceptor according to the present disclosure, by forming a heating element pattern without a hairpin section in the central portion of the susceptor plate where the embedding density of the heating element is high, it is possible to improve temperature uniformity across the entire region of the top surface of the susceptor and to significantly extend the lifespan of the heater pattern.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a view illustrating a heating element pattern of a conventional ceramic susceptor;

FIG. 2 is a schematic cross-sectional view of a ceramic susceptor according to an embodiment of the present disclosure;

FIG. 3A illustrates an example of a heating element pattern of the ceramic susceptor of the present disclosure;

FIG. 3B is a view illustrating the sharp curve portion of the curve section of a conventional resistance section of FIG. 1;

FIG. 3C is a view illustrating the change in the curve of the central resistance section of the present disclosure;

FIG. 4A illustrates an example of a two-zone arrangement structure of the heating element pattern of the ceramic susceptor of the present disclosure;

FIG. 4B illustrates another example of the two-zone arrangement structure of the heating element pattern of the ceramic susceptor of the present disclosure;

FIG. 5A is an enlarged view of portion PP1 in FIG. 4A; and

FIG. 5B is an enlarged view of portion PP2 in FIG. 4B.

### DETAILED DESCRIPTION OF THE EXEMPLARY EMBODIMENTS

Hereinafter, the present disclosure will be described in detail with reference to the accompanying drawings. Herein, like components in each drawing are denoted by like reference numerals if possible. In addition, detailed descriptions of already known functions and/or configurations will be omitted. In the following description, components necessary for understanding operations according to various embodiments will be mainly described, and descriptions of elements that may obscure the gist of the description will be omitted. In addition, some elements in the drawings may be exaggerated, omitted, or schematically illustrated. The size of each component does not entirely reflect the actual size. Therefore, the descriptions provided herein are not limited by the relative sizes or spacings of the components drawn in each drawing.

In describing the embodiments of the present disclosure, when a detailed description of the known technology related to the present disclosure is determined to unnecessarily obscure the subject matter of the present disclosure, the detailed description will be omitted. In addition, terms to be described later are defined in consideration of functions in the present disclosure, and may vary according to the intention, custom, or the like of a user or operator. Therefore, the definitions of the terms should be made based on the description throughout this specification. Terms used in the detailed description are only for describing the embodiments of the present disclosure, and should not be construed as limiting in any way. Unless expressly used otherwise, singular expressions include the meanings of plural expressions. As used herein, expressions such as “including” or “comprising” are intended to indicate any features, numbers, steps, operations, elements, or some or combinations thereof, and should not be construed to exclude the existence or possibility of one or more other features, numbers, steps, operations, elements, or some or combinations thereof, in addition to those described above.

In addition, terms such as “first” and “second” may be used to describe various components, but the components are not limited by the terms, and these terms are only used for the purpose of distinguishing one component from another.

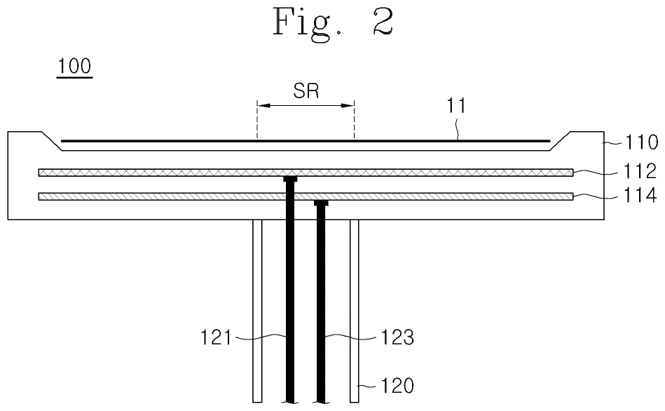

FIG. 2 is a schematic cross-sectional view of a ceramic susceptor 100 according to an embodiment of the present disclosure.

Referring to FIG. 2, the (ceramic) susceptor 100 according to an embodiment of the present disclosure includes an insulating plate 110 and a shaft 120.

The ceramic susceptor 100 according to an embodiment of the present disclosure is a semiconductor device that is used to support a substrate to be processed (hereinafter, referred to as a “processing-target substrate”) for various purpose, such as a semiconductor wafer, a glass substrate, or a flexible substrate, and to heat the processing-target substrate to a predetermined temperature, or to be used in a semiconductor process that uses plasma for plasma-enhanced chemical vapor deposition, dry etching, or the like.

The insulating plate 110 may be configured such that an electrode 112 for plasma generation or electrostatic chuck functionality and/or a heating element (electrode) 114 for substrate heating is arranged (embedded) at a predetermined interval between ceramic materials. The insulating plate 110 is configured to be capable of heating the processing-target substrate by using the heating element 114 while stably supporting the processing-target substrate and/or to be capable of performing a semiconductor process using plasma by using the electrode 112.

Although not illustrated in the drawings, in the ceramic susceptor 100 of the present disclosure, it is also possible to further place one or more electrostatic chuck electrodes to use the electrode 112 for plasma generation and additionally to support a substrate 11 placed on the insulating plate 110. For example, the one or more chuck electrodes may be further configured to be arranged (embedded) above or below the electrode 112 or the heating element 114 at a predetermined interval.

The insulating plate 110 may be a plate-like structure having a predetermined shape. For example, the insulating plate 110 may be a circular plate-like structure, but is not necessarily limited thereto. Here, the ceramic material may be at least one of Al₂O₃, Y₂O₃, Al₂O₃/Y₂O₃, ZrO₂, autoclaved lightweight concrete (AlC), TiN, AlN, TiC, MgO, CaO, CeO₂, TiO₂, BₓC_{y}, BN, SiO₂, SiC, YAG, mullite, and AlF₃, preferably aluminum nitride (AlN). Furthermore, each ceramic powder may optionally contain about 0.1 to 10%, preferably about 1 to 5% of yttrium oxide powder.

The shaft 120 is a hollow body having a through hole and is joined or coupled to the bottom surface of the insulating plate 110. The shaft 120 may be made of the same ceramic material as the insulating plate 110 and may be joined or coupled.

The electrode 112 or the one or more chuck electrodes may be made of tungsten (W), molybdenum (Mo), silver (Ag), gold (Au), niobium (Nb), titanium (Ti), aluminum nitride (AlN), or an alloy thereof, preferably molybdenum (Mo). The electrode 112 may be connected to a radio (RF) power source or to ground via a connecting rod 121 embedded in the hollow shaft 120, and the one or more chuck electrodes may be connected to a power source (DC or AC power source) for driving the chuck electrode via another connecting rod embedded in the hollow shaft 120. The electrode 112 may have a wire-type or sheet-type mesh structure. Here, the mesh structure is a structure in the form of a mesh fabricated by making multiple metals arranged in a first direction and multiple metals arranged in a second direction cross relative to each other in an alternating manner.

The heating element 114 is made of tungsten W, molybdenum Mo, an alloy or carbide thereof, or the like and has a high melting point and high resistance. The heating element 114 may be configured in a plate-like coil shape or the like by a heating wire (or a resistance wire or a heating electrode). In addition, the heating element 114 may be fabricated in a multi-layer structure for precise temperature control. In a semiconductor manufacturing process, the heating element 114 may be connected to the power supply via the connecting rod 123 embedded in the hollow shaft 120 to execute a function of heating a substrate to be processed (hereinafter, referred to as a “processing-target substrate”) placed on the insulating plate 110 to a predetermined constant temperature to perform a smooth deposition process, an etching process, or the like.

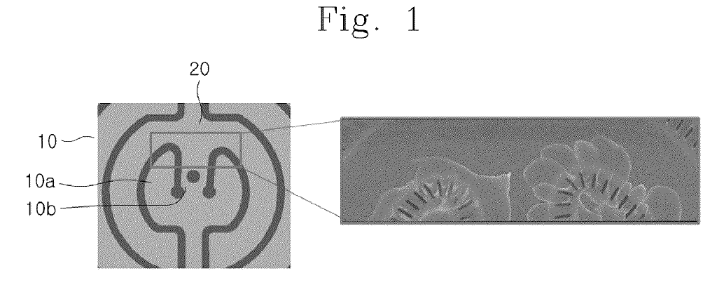

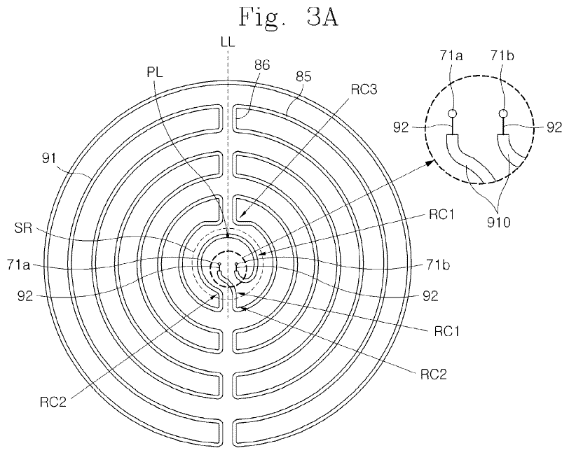

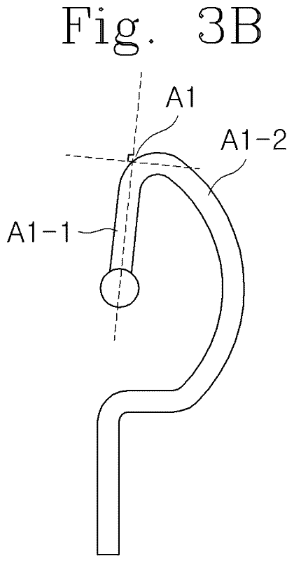

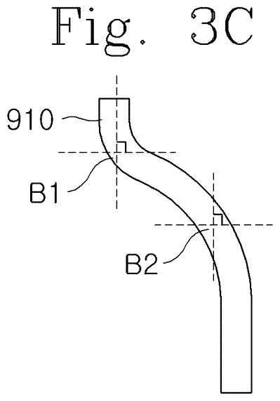

According to an embodiment of the present disclosure, a ceramic susceptor 100 has a heating element 114 made of a heating wire (or resistance wire), as illustrated in FIGS. 3A to 5B, in a central portion SR of a susceptor plate having a high embedding density, that is, in a region SR having a smaller diameter than the joint portion between the insulating plate 110 and the shaft 120, thereby forming a heating element pattern without a hairpin section, as illustrated in FIG. 1, thereby improving temperature uniformity over the entire region of the top surface of the susceptor and significantly extending the life of the heater pattern.

That is, the heating element pattern disposed in a smaller diameter region SR than the joint portion between the insulating plate 110 and the shaft 120 may be shaped in the form of a curve that bends at 90 degrees or more (e.g., 90 to 270 degrees) without a sharp curve. Here, the term “sharp curve” may refer to a case where the radius of curvature decreases and then increases, or increases and then decreases.

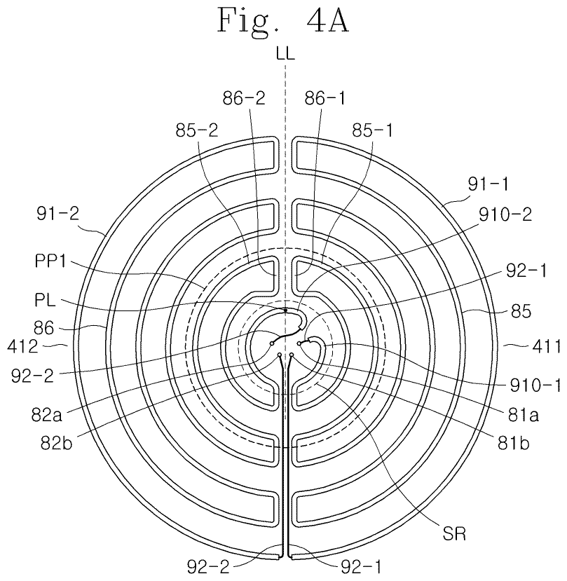

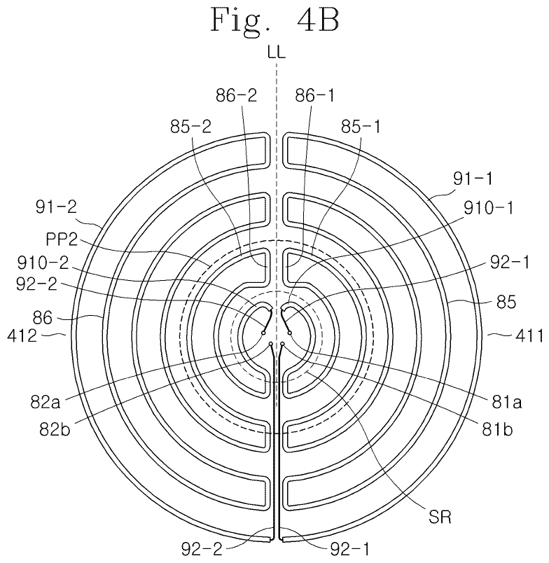

Hereinafter, the components of the present disclosure will be specifically described with reference to FIGS. 3A to 4B.

FIG. 3A illustrates an example of a pattern of the heating element 114 of the ceramic susceptor 100 of the present disclosure.

Referring to FIG. 3A, the heating element 114 may include a heating element pattern including a first resistance section 91 and first connecting sections 92 connected between a pair of first terminals 71a and 71b. The resistance section 91 may include multiple arc sections 85 extending in a circumferential direction and multiple folded sections 86 connecting the arc sections.

The first connecting sections 92 are connecting line portions for electrically connecting the pair of first terminals 71a and 71b at opposite ends of the first resistance sections 91. The first resistance section 91 and the first connecting sections 92 are made of materials with high resistance, such as tungsten (W), molybdenum (Mo), or an alloy or carbide thereof, and the resistance section 91 is a section configured to have resistance increased by processing the above-mentioned material into a coil shape (in some cases, a sawtooth zigzag shape or the like is also possible), thereby extending the electron travel distance.

When the first resistance section 91 is projected onto the plane of the insulating plate 110, the first central resistance section 910, which is arranged within a smaller diameter region SR than the joint portion between the insulating plate 110 and the shaft 120, may be shaped in the form of a curve that bends at an angle of 90 degrees or more (e.g., 90 to 270 degrees) without a sharp curve. It is also preferable to arrange the first pair of terminals 71a and 71b within the smaller diameter region SR than the joint portion between the insulating plate 110 and the shaft 120, but in some cases, the terminals 71a and 71b may be arranged in another region.

That is, the curve of the first central resistance section 910 refers to a curve without a sharp curve in the pattern of the first resistance section 91 arranged within the smaller diameter region SR than the joint portion of the shaft 120. Since the sharp curve section as described above appears and causes a hairpin section as in FIG. 1, it is disadvantageous to the temperature uniformity and the life of the heating element pattern. Therefore, the curve of the first central resistance section 910 may be formed as a section that does not have a sharp curve, that is, when bent points B1 and B2 of a curve are included, the curve may be formed as a section where the extension lines before and after the bent points B1 and B2 of the curve bend at 90 degrees or more (e.g., 90 to 270 degrees).

FIG. 3B is a view illustrating the sharp curve portion of the curve section of a conventional resistance section of FIG. 1. Referring to FIG. 3B, the resistance section in the center of the conventional plate as in FIG. 1 has a sharp curve shape in which the radius of curvature at a bent point A1 of the curve of a hairpin section near the pair of terminals 10a and 10b is smaller than the radius of curvature of the adjacent folded sections. Such a sharp curve shape may be, for example, a shape in which the extension lines A1-1 and A1-2 before and after the bent point A1 are bent at an angle less than 90 degrees. Since this is a region with high pattern density per unit area and, thus high heat generation density, cracks may easily occur in that region due to long-term use.

FIG. 3C is a view illustrating the change in the curve of the central resistance section 910 of the present disclosure. Referring to FIG. 3C, the curve of the first central resistance section 910 of the present disclosure may be designed such that the extension lines before and after one or more of the bent points B1 and B2 of the curve intersect at an angle of 90 degrees or more (e.g., 90 to 270 degrees), thereby eliminating sharp curve sections. For example, the extension lines before and after the bent point B1 may be a first extension line connecting a terminal (e.g., 71a) or a previous bent point (not illustrated) and the bent point B1, and a second extension line connecting the bent points B1 and B2. In addition, the extension lines before and after the above-mentioned bent point B2 may be a first extension line connecting the bent points B1 and B2 and a second extension line connecting the bent point B2 and the next bent point (not illustrated).

Furthermore, it is preferable to form the above-mentioned curve of the first central resistance section 910 arranged within the smaller diameter region SR than the joint portion of the shaft 120 to intersect at least once the extension line of an imaginary straight line LL passing through the space where the adjacent folded sections 86 of the resistance section 91 are spaced apart, as illustrated at a point PL in FIG. 3A. The space where the adjacent folded sections 86 are spaced apart includes the space between at least one pair of opposing folded sections 86. However, as illustrated in the drawing, the opposing folded sections 86 are not necessarily required to be formed axisymmetrically, as long as they are spaced apart. FIG. 3A illustrates that the space where the adjacent folded sections 86 are spaced apart is the space between three pairs of opposing folded sections 86.

When intersection points PL, PL1, and PL2 exist as described above, the empty space in which the pattern of the resistance section 91 does not exist between the folded sections 86 does not extend into the smaller diameter region SR than the joint portion of the shaft 120. Thus, in this case, the pattern of the resistance section 91 in the portion of the intersection points PL, PL1, and PL2 may improve the temperature uniformity therearound.

FIG. 4A illustrates an example of a two-zone arrangement structure of the pattern of the heating element 114 of the ceramic susceptor 100 of the present disclosure.

FIG. 4A illustrates another example of a two-zone arrangement structure of the pattern of the heating element 114 of the ceramic susceptor 100 of the present disclosure.

FIGS. 4A and 4B illustrate that the arrangement positions of central resistance sections 910-1 and 910-2 are different.

Referring to FIGS. 4A and 4B, the heating element 114 may include a first heating element pattern 411 including a first resistance section 91-1 and a first connecting section 92-1 connected between a first pair of terminals 81a and 81b, and a second heating element pattern 412 including a second resistance section 91-2 and a second connecting section 92-2 connected between a second pair of terminals 82a and 82b. Each of the resistance sections 91-1 and 91-2 may include multiple arc sections 85-1 and 85-2 extending in a circumferential direction and multiple folded sections 86-1 and 86-2 connecting the arc sections.

Each of the connecting sections 92-1 and 92-2 is a connecting line section for electrically connecting a pair of terminals 81a and 81b or 82a and 82b at opposite ends of each of the resistance sections 91-1 and 91-2. The first resistance section 91 and the first connecting sections 92 are made of materials with high resistance, such as tungsten (W), molybdenum (Mo), or an alloy or carbide thereof, and the resistance section 91 is a section configured to have resistance increased by processing the above-mentioned material into a coil shape (in some cases, a sawtooth zigzag shape or the like is also possible), thereby extending the electron travel distance.

When each of a first resistance section 91-1 and a second resistance section 91-2 is projected onto the plane of the insulating plate 110, the first central resistance section 910-1 of the first resistance section 91-1 and the second central resistance section 910-2 of the second resistance section 91-2, which are disposed within the smaller diameter region SR than the joint portion between the insulating plate 110 and the shaft 120, may be formed solely with curves without any sharp curves or straight sections. It is also preferable to arrange the first pair of terminals 81a and 81b and the second pair of terminals 82a and 82b within the smaller diameter region SR than the joint portion between the insulating plate 110 and the shaft 120, but in some cases, the first pair of terminals 81a and 81b and the second pair of terminals 82a and 82b may be arranged in another region.

That is, the curves of the central resistance sections 910-1 and 910-2 may be formed as curves in which the pattern of each resistance section 91-1 or 91-2 arranged within the smaller diameter region SR than the joint portion of the shaft 120 bends at an angle of 90 degrees or more (e.g., 90 to 270 degrees) without a sharp curve.

Furthermore, it is preferable to provide the curve of at least one (e.g., 910-2) of the central resistance sections 910-1 and 910-2 arranged within the smaller diameter region SR than the joint portion of the shaft 120 to intersect the extension line of the imaginary straight line LL passing through the space between the adjacent folded sections 86-1 86-2 of the resistance sections 91-1 and 91-2 at least once, as illustrated at a point PL in FIG. 4A. The region where the adjacent folded sections 86-1 and 86-2 of the resistance sections 91-1 and 91-2 are spaced apart includes a space between at least one pair opposing folded sections 86-1 and 86-2 of the first and second resistance sections 91-1 and 91-2. However, as illustrated in the drawings, the opposing folded sections 86-1 and 86-2 are not necessarily required to be formed axisymmetrically, as long as they remain spaced apart. FIG. 4A illustrates that the space where the adjacent folded sections 86-1 and 86-2 are spaced apart is the space between three pairs of opposing folded sections 86.

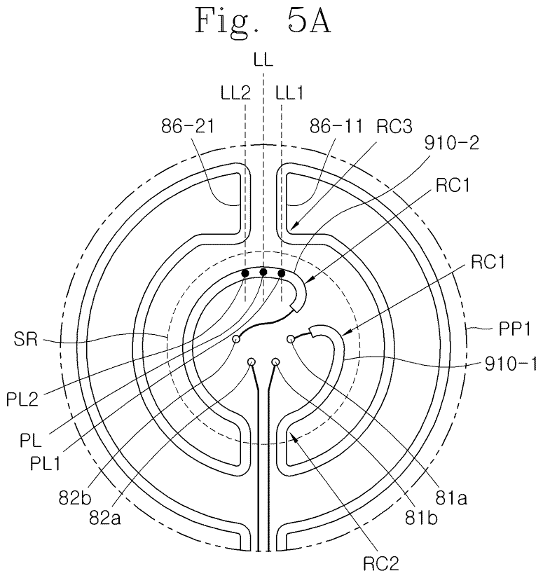

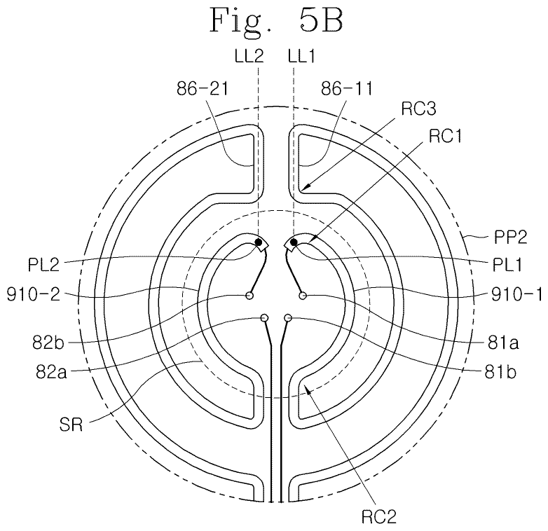

FIG. 5A is an enlarged view of portion PP1 in FIG. 4A.

Referring to FIG. 5A, the curve of at least one of the central resistance sections 910-1 and 910-2 arranged within the smaller diameter region SR than the joint portion of the shaft 120 may be formed to intersect, as illustrated at a point PL1, an imaginary extension line LL1 extending from the folded section 86-11 of the first central resistance section 910-1, which are closest to the first central resistance section 910-1 or the second central resistance section 910-2. In addition, the curve of at least one of the central resistance sections 910-1 and 910-2 arranged within the smaller diameter region SR than the joint portion of the shaft 120 may be formed to intersect, as illustrated at a point PL2, an imaginary extension line LL2 extending from the folded section 86-21 connected to the second central resistance section 910-2, which are closest to the first central resistance section 910-1 or the second central resistance section 910-2. FIG. 5B is an enlarged view of portion PP2 in FIG. 4B.

Referring to FIG. 5B, the curve of at least one of the central resistance sections 910-1 and 910-2 arranged within the smaller diameter region SR than the joint portion of the shaft 120 may be formed to intersect, as illustrated at points PL1 and PL2, the respective imaginary extension lines LL1 and LL2 extending from the folded section 86-11 connected to the first central resistance section 910-1 and the folded section 86-21 connected to the second central resistance section 910-2, which are closest to the first central resistance section 910-1 and the second central resistance section 910-2, respectively.

When intersection points PL, PL1, and PL2 exist as described above, the empty space in which the pattern of the resistance section 91 does not exist between the folded sections 86 does not extend into the smaller diameter region SR than the joint portion of the shaft 120. Thus, in this case, the pattern of the resistance section 91 in the portion of the intersection points PL, PL1, and PL2 may improve the temperature uniformity therearound.

In addition, in FIGS. 5A and 5B, the curves of each of the central resistance sections 910-1 and 910-2 arranged within the smaller diameter region SR than the joint portion of the shaft 120 include a curvature radius RC1 (e.g., R7) section near the terminal side of the central resistance section, a curvature radius RC2 (e.g., R2.5) section between the central resistance section and the folded section 86-1, and a curvature radius RC3 (e.g., R3.5) section between another arc section 85 and the folded section 86-1. Here, the units for the respective curvature radius values R7, R3.5, and R2.5 are in millimeters (mm).

For convenience, the above-mentioned curvature radii have been illustrated for the first resistance section 91-1 and the first central resistance section 910-1. However, the same relationships may also apply to the curvature radii of the second resistance section 91-2 and the second central resistance section 910-2. Furthermore, these relationships may be applied to both the first resistance section 91-1 and the first central resistance section 910-1, as well as the second resistance section 91-2 and the second central resistance section 910-2.

Similarly, the same relationships may also be applied to the first resistance section 91 and the first central resistance section 910 illustrated in FIG. 3A. That is, in FIG. 3A, at least one of the curves of the central resistance section 910 connected to the first terminal pair 71a and 71b within the smaller diameter region SR than the joint portion of the shaft 120 includes a curvature radius RC1 (e.g., R7) section near the terminal side (e.g., 71a) of the central resistance section 910, a curvature radius RC2 (e.g., R2.5) section between the central resistance section 910 and the folded section 86, and a curvature radius RC3 (e.g., R3.5) section between another arc section 85 and the folded section 86.

In other words, the curve of each of the central resistance sections 910-1 and 910-2 arranged within the smaller diameter region SR than the joint portion of the shaft 120 may formed such that the curvature radius (e.g., R7) of a section close to one of the pairs of terminal pairs 81a and 81b or 82a and 82b is larger than the curvature radii (e.g., R2.5 and R3.5) at all other folded sections 86-1 and 86-2. In this case, the curvature radius (e.g., R7) of a section close to one of the pairs of terminals 81a and 81b or 82a and 82b may be at least twice as large as the maximum curvature radius (e.g., R3.5) at all other folded sections 86-1 and 86-2.

Furthermore, the curve of the first central resistance section 910-1 may be formed such that the curvature radius (e.g., RC1=R7) of a section close to one of the first pair of terminals 81a and 81b is larger than the curvature radius (e.g., RC2=R2.5) of the closest folded section among the folded sections of the first resistance section 91-1. Similarly, the curve of the second central resistance section 910-2 may be formed such that the curvature radius (e.g., RC1=R7) of a section close to one of the second pair of terminals 82a and 82b is larger than the curvature radius (e.g., RC2=R2.5) of the closest folded section among the folded sections of the second resistance section 91-2.

As described above, with the ceramic susceptor 100 of the present disclosure, by forming a heating element pattern without a hairpin section in the central portion of the susceptor plate 110 where the embedding density of the heating element 114 is high, it is possible to improve temperature uniformity across the entire region of the top surface of the susceptor and to significantly extend the lifespan of the heater pattern.

In the foregoing, the present disclosure has been described based on specific details, such as concrete components, limited embodiments, and drawings, but these have been provided merely to aid a more comprehensive understanding of the present disclosure, and the present disclosure is not limited to the above-described embodiments. Various modifications and alterations may be made without departing from the essential characteristics of the present disclosure by a person ordinarily skilled in the art to which the present disclosure pertains. Therefore, the spirit of the present disclosure should not be limited to the described embodiments, and not only the appended claims, but also all technical ideas that are equivalent or have equivalent modifications to the claims should be construed as being included within the scope of the present disclosure.

What is claimed is:

1. A susceptor comprising:
an insulating plate in which a heating element is disposed; and
a shaft joined to a bottom portion of the insulating plate,
wherein the heating element comprises a first heating element pattern comprising a first resistance section and a first connecting section connected between a first pair of terminals, and
wherein, when the first resistance section is projected onto a plane of the insulating plate, the first resistance section comprises a first central resistance section disposed within a smaller diameter region than a joint portion between the insulating plate and the shaft.

2. The susceptor of claim 1, wherein the first resistance section comprises multiple arc sections extending in a circumferential direction and multiple folded sections connecting the arc sections, and
wherein a curve of the first central resistance section is formed to intersect an extension line of an imaginary straight line passing through a space between adjacent folded sections which are spaced apart from each other.

3. The susceptor of claim 1, wherein the first resistance section comprises multiple arc sections extending in a circumferential direction and multiple folded sections connecting the arc sections, and
wherein a curve of the first central resistance section is formed to intersect an extension line of an imaginary line extending from the folded section closest to the first central resistance section.

4. The susceptor of claim 1, wherein a curve of the first central resistance section is formed such that a curvature radius of a portion close to one of the first pair of terminals is larger than curvature radii of folded sections of the first resistance section.

5. The susceptor of claim 4, wherein the curvature radius of the portion close to one of the first pair of terminals is at least twice as large as a maximum curvature radius of the folded sections of the first resistance section.

6. The susceptor of claim 1, wherein a curve of the first central resistance section is formed such that a curvature radius of a portion close to one of the first pair of terminals is larger than a curvature radius of a closest folded section among the folded sections of the first resistance section.

7. The susceptor of claim 1, wherein the first pair of terminals is disposed within the smaller diameter region than the joint portion between the insulating plate and the shaft.

8. The susceptor of claim 1, wherein the heating element comprises a second heating element pattern comprising a second resistance section and a second connecting section connected between a second pair of terminals, and
wherein, when the first and second resistance sections are projected onto the plane of the insulating plate, the second resistance section comprises a second central resistance section disposed within the smaller diameter region than the joint portion between the insulating plate and the shaft.

9. The susceptor of claim 8, wherein the second resistance section comprises multiple arc sections extending in a circumferential direction and multiple folded sections connecting the arc sections, and
wherein at least one of curves of the first central resistance section and the second central resistance section is formed to intersect an extension line of an imaginary straight line passing through a space between adjacent folded sections which are spaced apart from each other.

10. The susceptor of claim 9, wherein the adjacent folded sections comprise folded sections that are adjacent to a folded section of the first resistance section and a folded section of the second resistance section.

11. The susceptor of claim 8, wherein the second resistance section comprises multiple arc sections extending in a circumferential direction and multiple folded sections connecting the arc sections, and
wherein at least one of curves of the first central resistance section and the second central resistance section is formed to intersect an extension line of an imaginary line extending from a folded section connected to the first central resistance section, which are closest to the first central resistance section or the second central resistance section.

12. The susceptor of claim 8, wherein the second resistance section comprises multiple arc sections extending in a circumferential direction and multiple folded sections connecting the arc sections, and
wherein at least one of the curves of the first central resistance section and the second central resistance section is formed to intersect an extended line of an imaginary line extending from a folded section connected to the second central resistance section, which are closest to the first central resistance section or the second central resistance section.

13. The susceptor of claim 8, wherein the second resistance section comprises multiple arc sections extending in a circumferential direction and multiple folded sections connecting the arc sections, and
wherein at least one of the curves of the first central resistance section and the second central resistance section is formed to intersect respective extension lines of imaginary lines extending from folded sections connected to the first central resistance section and the second central resistance section, which are closest to the first central resistance section and the second central resistance section, respectively.

14. The susceptor of claim 8, wherein curves of the first central resistance section and the second central resistance section are formed such that a curvature radius of a portion close to one of each pair of terminals is larger than the curvature radius at each of the folded sections of the first resistance section and the second resistance section.

15. The susceptor of claim 14, wherein a curvature radius of a portion close to one of each pair of terminals is at least twice as large as a maximum curvature radius of the folded sections of the first resistance section and the second resistance section.

16. The susceptor of claim 8, wherein a curve of the first central resistance section is formed such that a curvature radius of a portion close to one of the first pair of terminals is larger than a curvature radius of a closest folded section among the folded sections of the first resistance section, and
wherein a curve of the second central resistance section is formed such that a curvature radius of a portion close to one of the second pair of terminals is larger than a curvature radius of a closest folded section among the folded sections of the second resistance section.

17. The susceptor of claim 8, wherein the second pair of terminals is disposed within the smaller diameter region than the joint portion between the insulating plate and the shaft.
